(19) United States
(12) Patent Application Publication
(10) Pub. No.: US 2026/0164651 A1
(43) Pub. Date: Jun. 11, 2026

(54) SEMICONDUCTOR DEVICE

(71) Applicant: MICRON TECHNOLOGY, INC., BOISE, ID (US)

(72) Inventor: YASUYUKI SAKOGAWA, Higashihiroshima (JP)

(73) Assignee: MICRON TECHNOLOGY, INC., Boise, ID (US)

(21) Appl. No.: 19/402,526

(22) Filed: Nov. 26, 2025

Related U.S. Application Data
(60) Provisional application No. 63/728,712, filed on Dec. 6, 2024.

(51) Int. Cl. H10B 12/00

(52) U.S. Cl. CPC H10B 12/50; H10B 12/09

(57) ABSTRACT

An apparatus includes: a substrate having a first region, a second region and a third region between the first region and the second region; a first wiring provided in a first wiring layer above the first region; a second wiring provided in the first wiring layer above the second region; and a third wiring provided in a second wiring layer over the first wiring layer, the third wiring electrically couple the first wiring and the second wiring; wherein a first upper surface of the substrate in the first region is lower than a second upper surface of the substrate in the third region.

### CROSS-REFERENCE TO RELATED APPLICATIONS

This application claims the filing benefit of U.S. Provisional Application No. 63/728,712 filed Dec. 6, 2024. This application is incorporated by reference herein in its entirety and for all purposes.

### BACKGROUND

In a semiconductor device exemplified by, for example, a dynamic random-access memory (DRAM), electronic circuits each having many transistors are connected together by wirings. The wirings are connected to each other via contact plugs. When the connection between the wiring and the contact plug is inadequate, the semiconductor device may not operate properly.

### BRIEF DESCRIPTION OF THE DRAWINGS

FIG. 1 is a plan view showing a schematic configuration of a semiconductor device according to an embodiment.

FIG. 2 is a vertical sectional view showing a schematic configuration of a semiconductor device according to an embodiment. FIG. 2 is a vertical sectional view of a portion along line X-X in FIG. 1. FIG. 2 is also a diagram showing a method for manufacturing a semiconductor device according to the embodiment, and is a diagram showing an example of a schematic configuration at an exemplary process stage following a step shown in FIG. 10.

FIG. 3 is a vertical sectional view showing a schematic configuration of the semiconductor device according to the embodiment. FIG. 3 is a vertical sectional view of a portion along line Y-Y in FIG. 1 and FIG. 2.

FIGS. 4 to 10 are diagrams showing a process sequence of a method for manufacturing the semiconductor device according to the embodiment and are vertical sectional views showing an example of a schematic configuration at an exemplary process stage. FIGS. 4 to 10 are vertical sectional views of the portion along line X-X in FIG. 1.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

A semiconductor device according to an embodiment will now be described with reference to the drawings. In the following description, a dynamic random access memory (DRAM) will be described as an example of the semiconductor device. In the description of the embodiment, common or related elements, or substantially identical elements, are designated by the same reference symbols, and descriptions thereof will not be repeated. In the following drawings, the dimensions and dimensional ratios of respective portions may not necessarily match those in the embodiment. In the following description, an up-down direction and a left-right direction refer to directions in each case of the drawing with a semiconductor substrate located on the lower side.

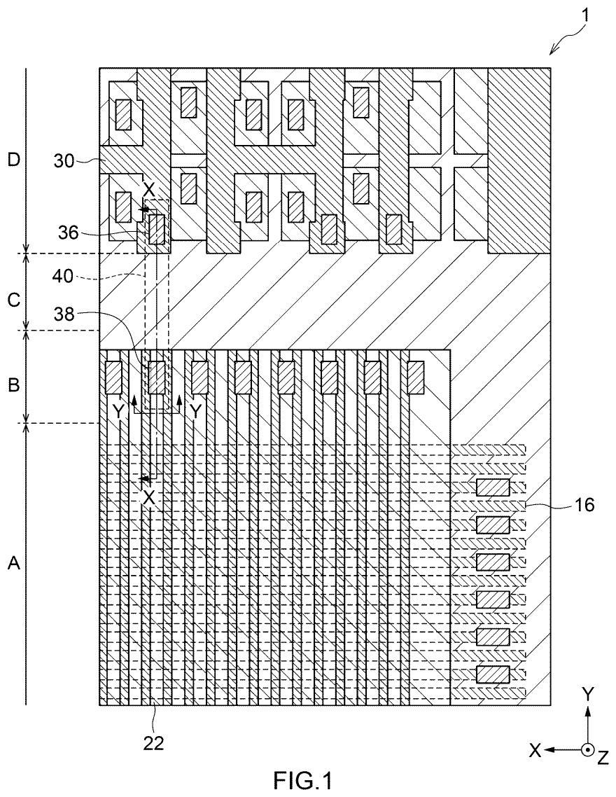

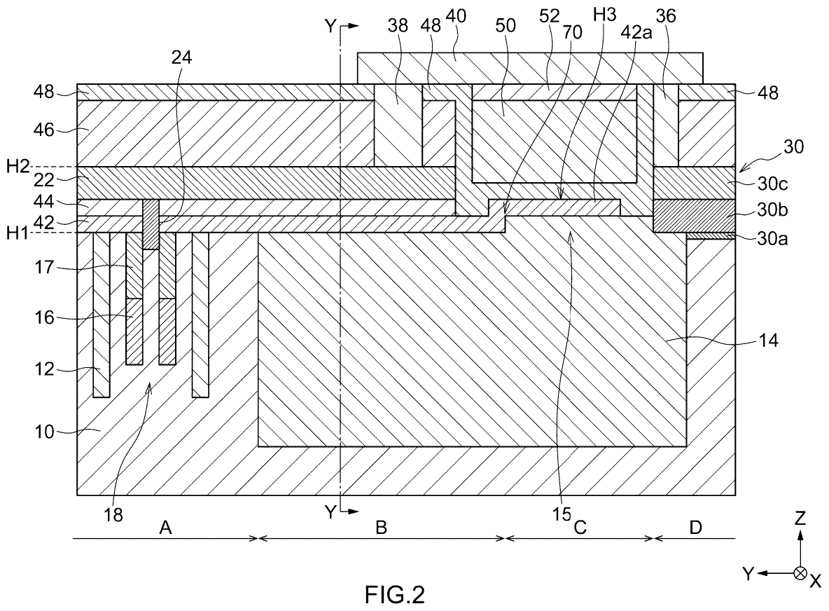

As shown in FIG. 1, the semiconductor device 1 according to the embodiment includes a first region A, a second region B, a third region C, and a fourth region D. The first region A is a memory cell array region, and includes a plurality of memory cells. Each memory cell includes, for example, one transistor and one capacitor, and stores information by accumulating electric charge in the capacitor. The second region B is a contact plug connection region in which a bitline lead-out contact plug 38 for connecting the bitline 22 and the wiring 40 is provided. As shown in FIG. 2, a step portion 15 is provided in the third region C. A peripheral isolation 14 is provided in the second region B and the third region C. The fourth region D is an array circuit region, and includes, for example, peripheral circuits such as a memory cell control circuit such as a column selector. The peripheral isolation 14 provided in the second region B and the third region C includes a trench isolation that electrically or physically separates the first region A and the fourth region D from each other.

As shown in FIG. 1, a plurality of word-lines 16 each extending in an X-direction, and a plurality of bitlines 22 each extending in a Y-direction are arranged in the first region A. Each of the word-lines 16 and each of the bitlines 22 are perpendicular to each other. A memory cell is arranged at the intersection of each word-line 16 and each bitline 22. Peripheral wirings 30 for transistors included in the array circuit are arranged in the fourth region D.

The bitlines 22 and the peripheral wirings 30 are connected by the wirings 40 via the peripheral contact plugs 36 and the bitline lead-out contact plugs 38. The wirings 40 and the bitlines 22 are connected via the bitline lead-out contact plugs 38. The bitline lead-out contact plugs 38 are provided in the second region B. The wirings 40 and the peripheral wirings 30 are connected via the peripheral contact plugs 36. The peripheral contact plugs 36 are provided in the fourth region D.

FIG. 1 shows one wiring 40 for connecting the bitline 22 and the peripheral wiring 30 as an example of the wiring for connecting the bitline 22 and the peripheral wiring 30. Although not shown in FIG. 1, actually, the bitlines 22 and the array circuit including the peripheral wirings 30 arranged in the fourth region D are connected by wirings.

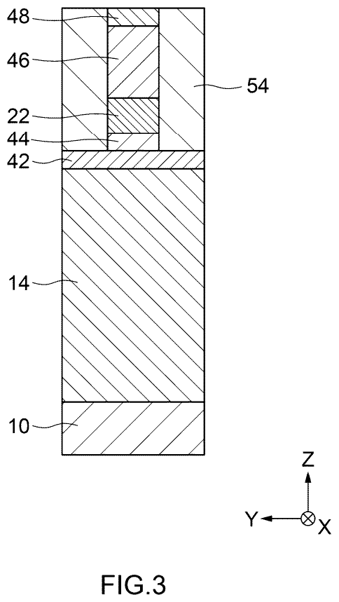

As shown in FIGS. 2 and 3, the semiconductor device 1 includes the bitlines 22, the bitline lead-out contact plugs 38, the peripheral contact plugs 36, and the wirings 40 that are provided on a semiconductor substrate 10. A plurality of active regions 18 partitioned by isolations 12 are arranged on the semiconductor substrate 10 in the first region A. The active region 18 is provided with a word-line 16 included in a memory cell transistor, a cap insulating portion 17 provided on the word-line 16, and a bit contact 24 for connecting the active region 18 and the bitline 22. The bitlines 22 are arranged in the first region A and the second region B.

In the second region B and the third region C, the peripheral isolation 14 and a first insulating film 42 are arranged on the semiconductor substrate 10. The bitline 22 is disposed on the first insulating film 42. In the third region C, the bitline lead-out contact plug 38 for connecting the bitline 22 and the wiring 40 is provided, and the peripheral wiring 30 included in the transistor of the array circuit is also provided. The region in which the peripheral isolation 14 is provided can be divided into the second region B and the third region C.

The peripheral wirings 30 are provided in the fourth region D. The peripheral wiring 30 includes a first conductive portion 30b and a second conductive portion 30c. A gate insulating film 30a is provided below the peripheral wiring 30. The peripheral contact plug 36 is provided on the upper surface of the peripheral wiring 30, and the peripheral wiring 30 and the wiring 40 are connected to each other via the peripheral contact plug 36. The bitline 22 and the second conductive portion 30c are included in the same layer.

In the third region C, the step portion 15 is disposed at an upper portion of the peripheral isolation 14, and the first insulating film 42 disposed on the step portion 15 is formed as a step portion 42a reflecting the shape of the step portion 15. The step portion 15 serves as a part of the peripheral isolation 14. The step portion 15 or the step portion 42a is located below the wiring 40 and between the bitline lead-out contact plug 38 and the peripheral contact plug 36. The layer in which the bitline 22 and the second conductive portion 30c are disposed is lower than the layer of the wiring 40. A step portion formed between the upper surface of the peripheral isolation 14 in the second region B and the upper surface of the peripheral isolation 14 in the third region C serves as a border 70. The border 70 is also an end portion of the step portion 15. The border 70 is disposed underneath the wiring 40.

A fourth insulating film 48 is disposed above the step portion 15 or the step portion 42a, above which a fifth insulating film 50 and a sixth insulating film 52 are disposed. The third insulating film 46 and the fourth insulating film 48 are disposed above the bitline 22. The wiring 40 is disposed above the fourth insulating film 48 and the sixth insulating film 52.

When the peripheral isolation 14 and the first insulating film 42 are formed of the same material, the peripheral isolation 14 and the first insulating film 42 are integrated with each other, and thus the boundary between the peripheral isolation 14 and the first insulating film 42 is unclear. Therefore, a step portion including the step portion 15 and the step portion 42a is disposed at upper portions of the peripheral isolation 14 and the first insulating film 42. The third insulating film 46, the fifth insulating film 50, and the sixth insulating film 52 are disposed between the step portion including the step portion 15 and the step portion 42a and the wiring 40.

The level H1 of the upper surface of the semiconductor substrate 10 in the first region A is substantially the same as the level H1 of the upper surface of the peripheral isolation 14 in the second region B. In other words, the upper surface of the semiconductor substrate 10 in the first region A and the upper surface of the peripheral isolation 14 in the second region B form a continuous flat surface. The level H1 of the upper surface of the semiconductor substrate 10 in the first region A and the level H1 of the upper surface of the peripheral isolation 14 in the second region B are lower than the level H3 of the upper surface of the step portion 15.

Furthermore, the level H2 of the upper surface of the bitline 22 in the first region A is substantially the same as the level H2 of the upper surface of the bitline 22 in the second region B. In other words, the upper surface of the bitline 22 in the first region A and the second region B forms a continuous flat surface. Note that the levels H1, H2 are defined as distances from an arbitrary reference position in the Z-direction, for example, they are defined as distances from the bottom surface of the semiconductor substrate 10 in the Z-direction.

As shown in FIG. 3, the third insulating film 46 and the fourth insulating film 48 are disposed on the bitline 22 in order from the insulating film closest to the bitline 22. The level H1 of the upper surface of the semiconductor substrate 10 in the first region A is substantially the same as the level H2 of the upper surface of the bitline 22 in the second region B. Therefore, the width of the bitline 22 in the second region B is not substantially narrower than the width of the bitline 22 in the first region A, and the bitline 22 does not disappear in the second region B.

Next, a method for manufacturing the semiconductor device 1 according to the embodiment will be described.

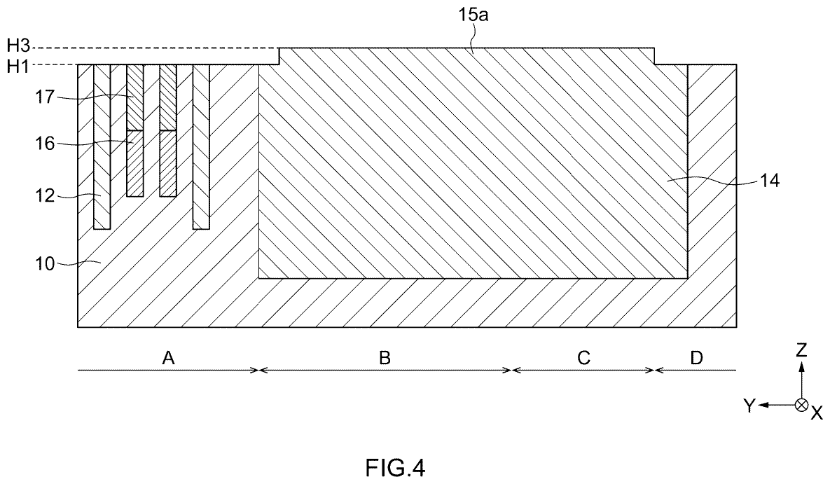

As shown in FIG. 4, the isolations 12, the word-lines 16, and the cap insulating portions 17 are formed in the first region A of the semiconductor substrate 10. Furthermore, the peripheral isolation 14 is formed in the second region B, the third region C, and a part of the fourth region D of the semiconductor substrate 10. The semiconductor substrate 10 includes single crystal silicon. The isolations 12 and the peripheral isolation 14 are trench isolation regions formed by forming grooves in the semiconductor substrate 10 and then filling the grooves with an insulating material. The isolations 12 and the peripheral isolation 14 include, for example, silicon dioxide (SiO₂). The isolation 12 has a function of electrically or physically separating adjacent elements from each other. The peripheral isolation 14 has a function of electrically or physically separating the first region A and the fourth region D from each other.

The word-lines 16 and the cap insulating portions 17 are formed, for example, by forming respective materials using chemical vapor deposition (CVD) after grooves are formed in the semiconductor substrate 10, and then performing chemical mechanical polishing (CMP) until the upper surface of the semiconductor substrate 10 is exposed. The word-lines 16 include a conductive material such as titanium (Ti). The cap insulating portions 17 include an insulating material such as silicon nitride (SiN).

The peripheral isolation 14 includes a step portion 15a at an upper portion thereof. The level H1 of the upper surface of the semiconductor substrate 10 is lower than the level H3 of the upper surface of the step portion 15a. The Levels H1, H3 are defined as distances from an arbitrary reference position in the Z-direction, for example, as distances from the bottom surface of the semiconductor substrate 10 in the Z-direction.

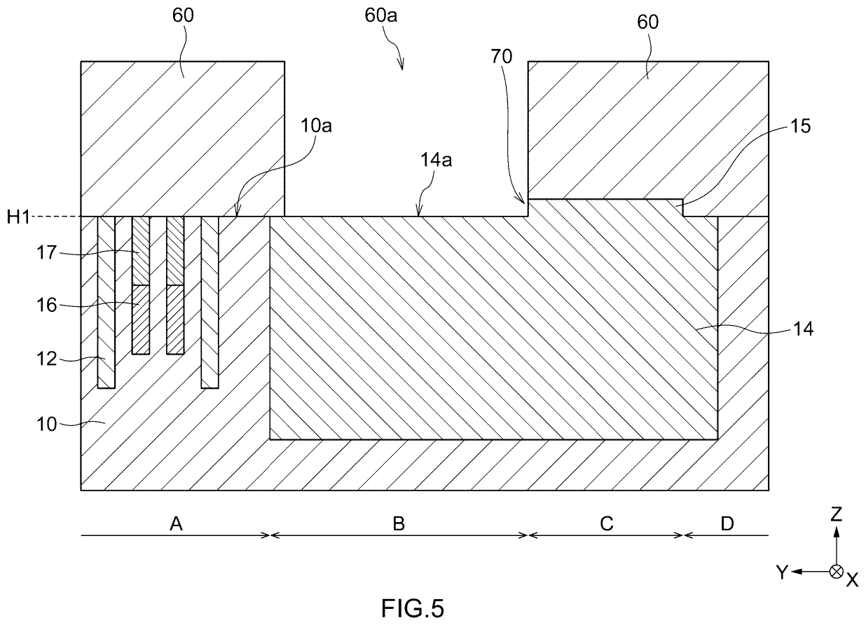

Next, as shown in FIG. 5, a photoresist 60 having an opening portion 60a is formed in the second region B. The photoresist 60 is formed by a known lithography technique. Next, anisotropic or isotropic etching is performed using the photoresist 60 as a mask to remove the step portion 15a of the opening portion 60a. As a result, the heights or levels of the upper surface 10a of the first region A and the upper surface 14a of the second region B become substantially the same, so that the upper surface 10a of the first region A and the upper surface 14a of the second region B form a substantially continuous flat surface. A part of the step portion 15a under the photoresist 60 remains, and it serves as the step portion 15. An end portion of the step portion 15 serves as a border 70 between the second region B and the third region C.

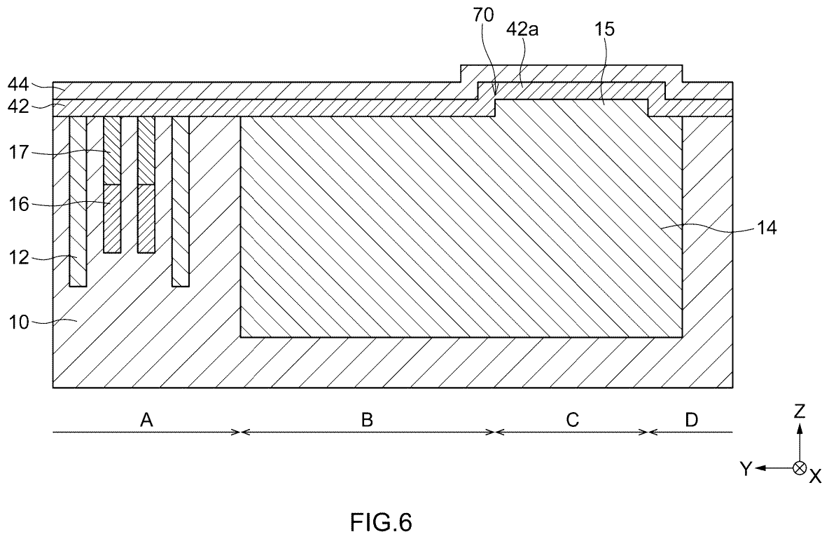

Next, as shown in FIG. 6, after the photoresist 60 is removed, a first insulating film 42 and a second insulating film 44 are formed so as to cover the upper surfaces of the semiconductor substrate 10 and the peripheral isolation 14 in the first region A, the second region B, the third region C, and the fourth region D. The first insulating film 42 includes silicon dioxide, and the second insulating film 44 includes, for example, silicon nitride. The first insulating film 42 and the second insulating film 44 are formed by, for example, CVD. A step portion 42a reflecting the shape of the step portion 15 is formed on the step portion 15 of the peripheral isolation 14.

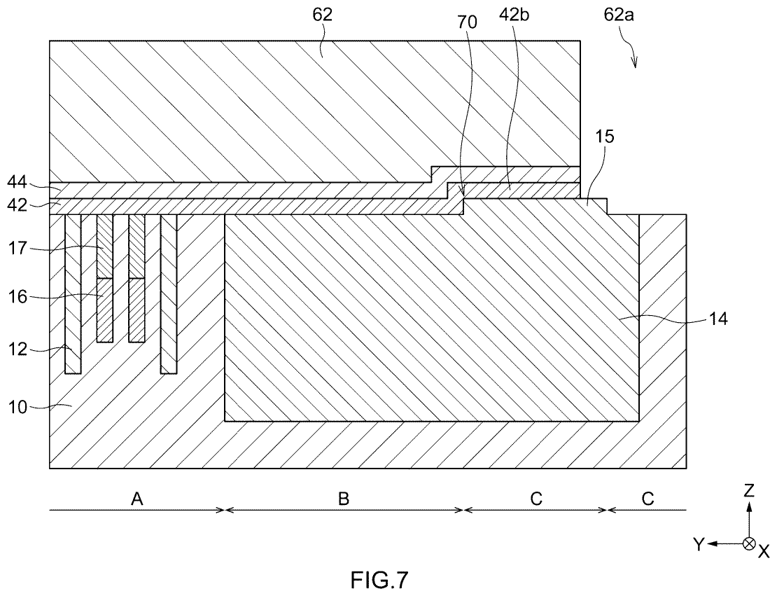

Next, as shown in FIG. 7, a photoresist 62 having an opening portion 62a formed in the fourth region D and a part of the third region C is formed. The photoresist 62 is formed by a known lithography technique. Next, anisotropic or isotropic etching is performed using the photoresist 62 as a mask to remove the second insulating film 44 and the first insulating film 42 in the opening portion 62a.

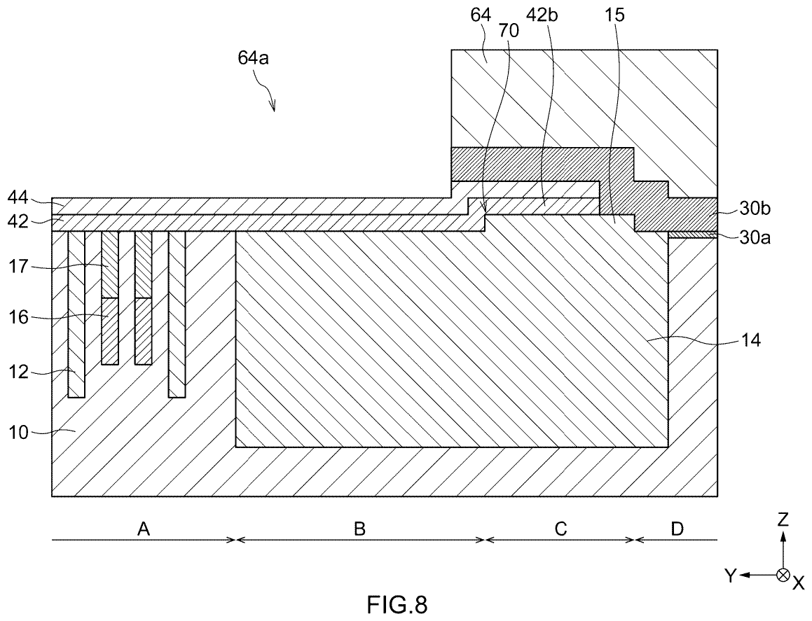

Next, as shown in FIG. 8, a gate insulating film 30a is formed on the semiconductor substrate 10 in the fourth region D, and then a first conductive portion 30b is formed in the first region A, the second region B, the third region C, and the fourth region D. The gate insulating film 30a includes an insulator such as silicon oxynitride (SiON) or hafnium oxide (HfO). The gate insulating film 30a is formed by, for example, CVD. The first conductive portion 30b includes polysilicon doped with impurities such as phosphorus, arsenic, or boron. The first conductive portion 30b is formed by, for example, CVD.

Next, a photoresist 64 having an opening portion 64a formed in the first region A and the second region B is formed. The photoresist 64 is formed by a known lithography technique. Next, anisotropic dry etching is performed using the photoresist 64 as a mask to remove the first conductive portion 30b in the opening portion 64a.

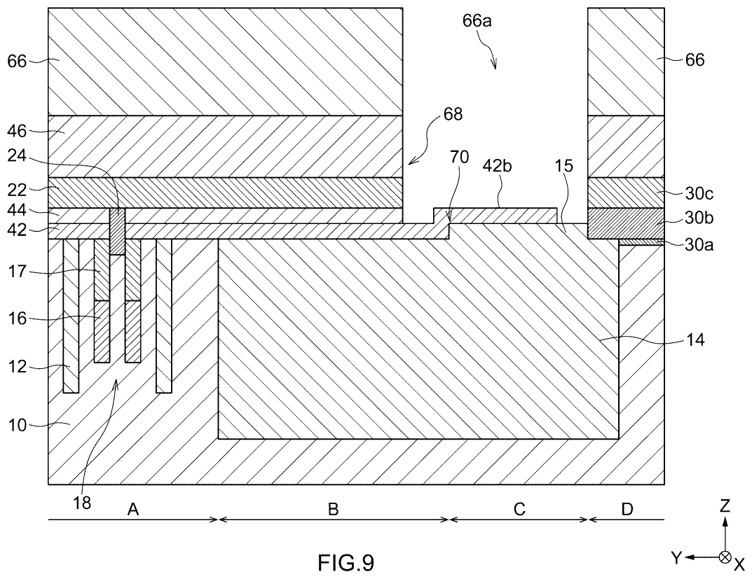

Next, as shown in FIG. 9, a conductive material that will serve as bitlines 22 and a second conductive portion 30c is formed, and then a third insulating film 46 is formed. The conductive material includes a conductive material such as tungsten (W). The third insulating film 46 includes an insulating material such as silicon nitride. The conductive material and the third insulating film 46 are formed by, for example, CVD. Next, the conductive material is subjected to patterning to form the bitlines 22 and the peripheral wirings 30. This patterning is performed using, for example, a known multi-patterning technique.

Next, a photoresist 66 having an opening portion 66a formed in a part of the second region B and the third region C. The photoresist 66 is formed by a known lithography technique. Next, anisotropic dry etching is performed using the photoresist 66 as a mask to remove the third insulating film 46, the conductive material, and the second insulating film 44 in the opening portion 66a. As a result, the third insulating film 46, the conductive material, the first conductive portion 30b, and the second insulating film 44 are removed, thereby forming a groove 68 in which the upper surfaces of parts of the first insulating film 42 and the peripheral isolation 14 are exposed. As a result, the bitlines 22 and the peripheral wiring 30 are formed.

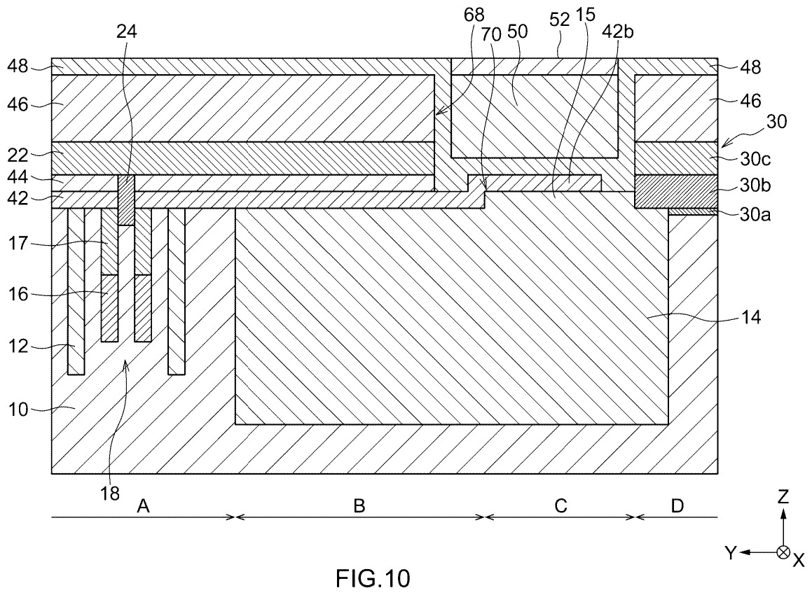

Next, as shown in FIG. 10, a fourth insulating film 48 is formed so as to cover the upper surface of the third insulating film 46 and the bottom and side surfaces of the groove 68, and then a fifth insulating film 50 is formed so as to fill at least the inside of the groove 68. The fourth insulating film 48 includes an insulating material such as silicon nitride. The fifth insulating film 50 includes an insulating material such as silicon dioxide. The fourth insulating film 48 and the fifth insulating film 50 are formed by, for example, CVD.

Next, the fifth insulating film 50 is etched back or subjected to CMP using the fourth insulating film 48 as a stopper. Next, a sixth insulating film 52 is formed so as to fill the groove formed in the upper portion of the fifth insulating film 50. The sixth insulating film 52 is formed by, for example, CVD. Although not shown, after this, a capacitor to be connected to an active region 18 is formed in the first region A.

Next, as shown in FIG. 2, a contact hole is formed for each of the bitlines 22 and the peripheral wirings 30 so as to extend from the upper surface of the fourth insulating film 48 to the upper surface of the bitline 22, and a conductive material is filled in the contact holes to form the bitline lead-out contact plugs 38 and the peripheral contact plugs 36.

The contact holes are formed using a known lithography technique and anisotropic dry etching. The bitline lead-out contact plugs 38 and the peripheral contact plugs 36 include a conductive material such as titanium or tungsten. The bitline lead-out contact plugs 38 and the peripheral contact plugs 36 are formed by forming a conductive material by CVD and performing etch-back or CMP, thereby burying the conductive material in the contact holes.

Next, wirings 40 to be connected to the peripheral contact plugs 36 and the bitline lead-out contact plugs 38 are formed. The wirings 40 are formed by forming a conductive material such as titanium or tungsten by, for example, CVD, and then performing a known lithography technique and anisotropic dry etching. Through the above steps, the semiconductor device 1 according to the embodiment is formed.

As above, DRAM is described as an example of the semiconductor device according to the embodiment, but the above description is merely one example and not intended to be limited to DRAM. Memory devices other than DRAM, such as static random-access memory (SRAM), flash memory, erasable programmable read-only memory (EPROM), magnetoresistive random-access memory (MRAM), and phase-change memory for example can also be applied as the semiconductor device. Furthermore, devices other than memory, including logic ICs such as a microprocessor and an application-specific integrated circuit (ASIC), for example, are also applicable as the semiconductor device according to the foregoing embodiment.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a substrate having a first region, a second region and a third region between the first region and the second region;
a first wiring provided in a first wiring layer above the first region;
a second wiring provided in the first wiring layer above the second region; and
a third wiring provided in a second wiring layer over the first wiring layer, the third wiring electrically couple the first wiring and the second wiring;
wherein a first upper surface of the substrate in the first region is lower than a second upper surface of the substrate in the third region.

2. The apparatus of claim 1, further comprising a trench isolation in the third region of the substrate, the trench isolation physically separating the first region and the second region.

3. The apparatus of claim 2, wherein the third region is divided into a fourth region adjacent to the first region and a fifth region adjacent to the second region;
wherein the first upper surface of the substrate in the first region and a third upper surface of the substrate in the fourth region are substantially the same level; and
wherein the second upper surface of the substrate is in the fifth region.

4. The apparatus of claim 3, wherein the first wiring also extends in the fourth region; and
wherein a fourth upper surface of the first wiring in the first region and a fifth upper surface of the first wiring in the fourth region are substantially the same level.

5. The apparatus of claim 3, wherein the trench isolation has the third upper surface in the fourth region and the second upper surface in the fifth region.

6. The apparatus of claim 5, further comprising a first contact plug in the fourth region and a second contact plug in the second region;
wherein the first contact plug is connected between the first wiring and the third wiring; and
wherein the second contact plug is connected between the second wiring and the third wiring.

7. The apparatus of claim 6, wherein a border between the fourth region and the fifth region is underneath the third wiring.

8. The apparatus of claim 7, wherein the trench isolation comprises insulator.

9. An apparatus comprising:
a substrate having a memory cell array region, an array circuit region and an isolation region between the memory cell array region and the array circuit region;
a bitline provided in a first wiring layer above the memory cell array region;
a first wiring provided in the first wiring layer above the array circuit region; and
a second wiring provided in a second wiring layer over the first wiring layer, the second wiring electrically couple the bitline and the first wiring;
wherein a first upper surface of the substrate in the memory cell array region is lower than a second upper surface of the substrate in the isolation region.

10. The apparatus of claim 9, further comprising a trench isolation in the isolation region of the substrate, the trench isolation physically separating the memory cell array region and the array circuit region.

11. The apparatus of claim 10, wherein the isolation region is divided into a first region adjacent to the memory cell array region and a second region adjacent to the array circuit region and
wherein the first upper surface of the substrate in the memory cell array region and a third upper surface of the substrate in the first region are substantially the same level; and
wherein the second upper surface of the substrate is in the second region.

12. The apparatus of claim 11, wherein the bitline also extends in the first region; and
wherein a fourth upper surface of the bitline in the memory cell array region and a fifth upper surface of the bitline in the first region are substantially the same level.

13. The apparatus of claim 11, wherein the trench isolation has the third upper surface in the fourth region and the second upper surface in the fifth region.

14. The apparatus of claim 13, further comprising a first contact plug in the first region and a second contact plug in the array circuit region;
wherein the first contact plug is connected between the bitline and the second wiring; and
wherein the second contact plug is connected between the first wiring and the second wiring.

15. The apparatus of claim 14, wherein a border between the fourth region and the fifth region is underneath the second wiring.

16. The apparatus of claim 15, wherein the trench isolation comprises insulator.

17. An apparatus comprising:
a substrate having a first region, a second region, a third region and a fourth region, wherein the second region is provided between the first region and the third region and wherein the third region is provided between the second region and the fourth region;
a first wiring provided in a first wiring layer above the first region and the second region; and
a second wiring provided in the first wiring layer above the fourth region; and
a third wiring provided in a second wiring layer over the first wiring layer, the third wiring electrically coupled to the first wiring and the second wiring;
wherein a first upper surface of the substrate in the first region and a second upper surface of the substrate in the second region are lower than a third upper surface of the substrate in the third region; and
wherein the first upper surface and the second upper surface are substantially the same level.

18. The apparatus of claim 17, wherein a fourth upper surface of the first wiring in the first region and a fifth upper surface of the first wiring in the second region are substantially the same level.

19. The apparatus of claim 18, further comprising a trench isolation including insulating material in the second region and the third region, the trench isolation physically separating the first region and the fourth region.

20. The apparatus of claim 19, wherein a border between the second region and the third region is underneath the third wiring.
